(19) United States
(12) Patent Application Publication
(10) Pub. No.: US 2026/0229471 A1
(43) Pub. Date: Aug. 6, 2026

(54) SUBSTRATE PROCESSING APPARATUS, SUBSTRATE PROCESSING METHOD, METHOD OF MANUFACTURING SEMICONDUCTOR DEVICE AND NON-TRANSITORY COMPUTER-READABLE RECORDING MEDIUM

(71) Applicant: Kokusai Electric Corporation, Tokyo (JP)

(72) Inventors: Masaki MUROBAYASHI, Toyama-shi (JP); Tomoki HORITA, Toyama-shi (JP)

(73) Assignee: Kokusai Electric Corporation, Tokyo (JP)

(21) Appl. No.: 19/634,277

(22) Filed: Mar. 31, 2026

Related U.S. Application Data
(63) Continuation of application No. PCT/JP2023/036421, filed on Oct. 5, 2023.

(51) Int. Cl. H01J 37/32; H10P 14/00; H10P 50/20

(52) U.S. Cl. CPC H01J 37/3299; H01J 37/32449; H01J 2237/24564; H01J 2237/3323; H10P 14/00; H10P 50/20

(57) ABSTRACT

There is provided a technique that includes: a process vessel in which a substrate is accommodated and processed; a plasma generator configured to generate a plasma in the process vessel; a calculator configured to calculate a cumulative amount of an electric power output by the plasma generator during a processing of the substrate; a memory configured to store, as a master cumulative amount, the cumulative amount at an end of the processing of the substrate when a result of the processing of the substrate is normal; and a controller configured to be capable of controlling a progress of the processing of the substrate based on a recipe defining process conditions containing a process time for the substrate, and capable of calculating a correction time for the process time from a difference between the cumulative amount calculated by the calculator and the master cumulative amount.

### DESCRIPTION

### CROSS-REFERENCE TO RELATED PATENT APPLICATION

This application is a bypass continuation application of PCT International Application No. PCT/JP2023/036421, filed on October 5, 2023, in the WIPO, the entire contents of which are hereby incorporated by reference.

### BACKGROUND

### 1. Field

The present disclosure relates to a substrate processing apparatus, a substrate processing method, a method of manufacturing a semiconductor device and a non-transitory computer-readable recording medium.

### 2. Related Art

According to some related arts, as a part of a manufacturing process of a semiconductor device, a process of supplying a plasma to a substrate (hereinafter, also referred to as a “plasma processing” or a “plasma treatment”) may be performed.

### SUMMARY

According to the present disclosure, there is provided a technique capable of stabilizing a quality of a plasma processing performed on a substrate.

According to the embodiments of the present disclosure, there is provided a technique that includes: a process vessel in which a substrate is accommodated and processed; a plasma generator configured to generate a plasma in the process vessel; a calculator configured to calculate a cumulative amount of an electric power output by the plasma generator during a processing of the substrate; a memory configured to store, as a master cumulative amount, the cumulative amount at an end of the processing of the substrate when a result of the processing of the substrate is normal; and a controller configured to be capable of controlling a progress of the processing of the substrate based on a recipe defining process conditions containing a process time for the substrate, and capable of calculating a correction time for the process time from a difference between the cumulative amount calculated by the calculator and the master cumulative amount.

### BRIEF DESCRIPTION OF THE DRAWINGS

FIG. 1 is a diagram schematically illustrating a configuration of a substrate processing apparatus according to one or more embodiments of the present disclosure.

FIG. 2 is a block diagram schematically illustrating a configuration of a controller and its related components of the substrate processing apparatus according to the embodiments of the present disclosure.

FIG. 3 is a functional block diagram schematically illustrating a configuration of the substrate processing apparatus configured to perform a process time correction sequence according to the embodiments of the present disclosure.

FIG. 4 is a flow chart schematically illustrating a substrate processing sequence according to the embodiments of the present disclosure.

FIG. 5 is a flow chart schematically illustrating the process time correction sequence according to the embodiments of the present disclosure.

FIG. 6A is a diagram schematically illustrating an example of a control by which a process time is adjusted to be increased according to the embodiments of the present disclosure, FIG. 6B is a diagram schematically illustrating an example of a control by which the process time is adjusted to be decreased according to the embodiments of the present disclosure, and FIG. 6C is a diagram schematically illustrating an example of a control by which the process time is not adjusted according to the embodiments of the present disclosure.

FIG. 7 is a diagram schematically illustrating an example of a screen output by an input/output device provided in the substrate processing apparatus according to the embodiments of the present disclosure.

### DETAILED DESCRIPTION

### <Embodiments of Present Disclosure>

Hereinafter, one or more embodiments (hereinafter, also simply referred to as “embodiments”) according to the present disclosure will be described with reference to the drawings. For example, the drawings used in the following descriptions are all schematic, and a relationship between dimensions of each component and a ratio of each component shown in the drawing may not always match the actual ones. In addition, even between the drawings, the relationship between the dimensions of each component and the ratio of each component may not always match.

### (1) Configuration of Substrate Processing Apparatus

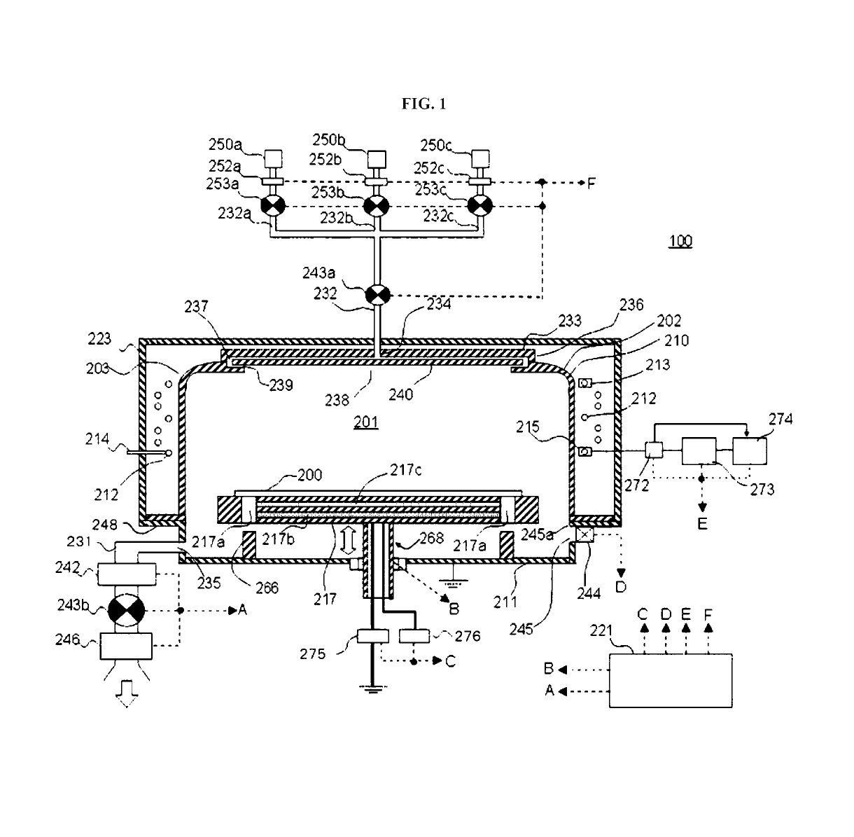

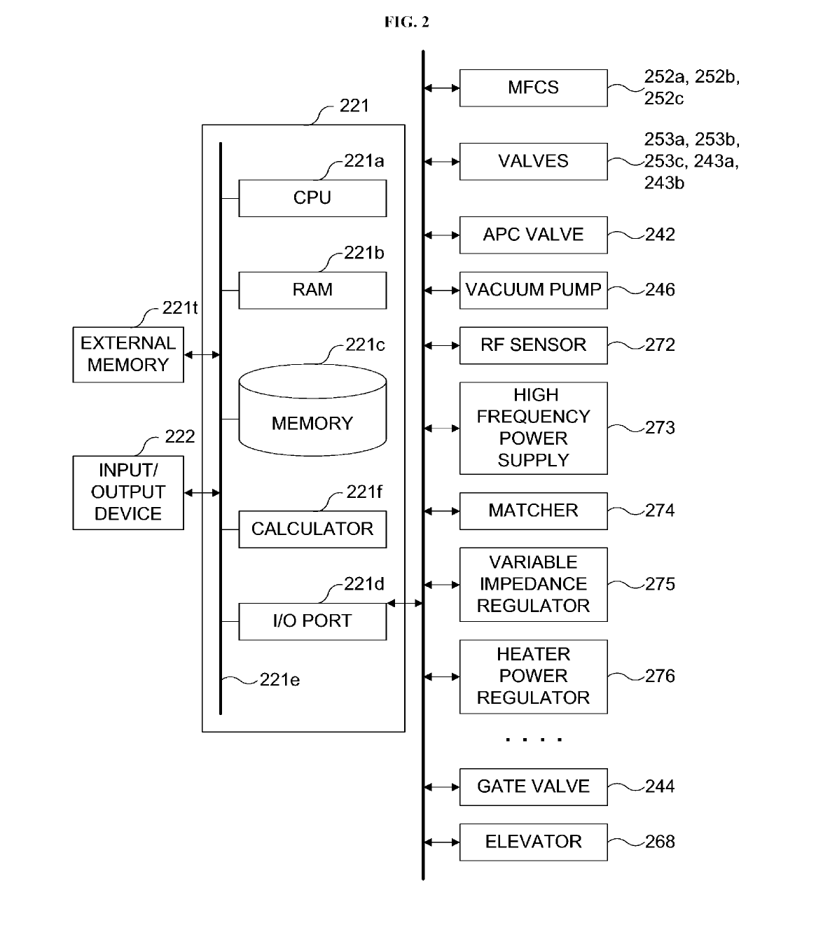

First, a configuration of a substrate processing apparatus (hereinafter, also referred to as a “processing apparatus”) 100 will be described with reference to FIGS. 1 to 3 and 7.

### <Process Chamber>

As shown in FIG. 1, the processing apparatus 100 includes a process furnace 202 in which a wafer 200 serving as a substrate is processed. The process furnace 202 includes a process vessel 203 configured to accommodate the wafer 200. The process vessel 203 is constituted by an upper vessel (which is of a dome shape) 210 and a lower vessel (which is of a bowl shape) 211. For example, the upper vessel 210 is made of a non-metallic material such as aluminum oxide (Al₂O₃) and quartz (SiO₂), and the lower vessel 211 is made of a metallic material such as aluminum (Al).

A process chamber 201 provided in the process vessel 203 is constituted by: a space (that is, a plasma generation space) in which a plasma is generated; and a space (that is, a substrate processing space) communicating with the plasma generation space. The wafer 200 is processed in the substrate processing space. The plasma generation space refers to the space (which is within the process chamber 201) whose outer periphery is surrounded by a resonance coil 212 described later. The substrate processing space refers to the space (which is within the process chamber 201) in which the wafer 200 is accommodated. The substrate processing space is provided below the plasma generation space.

An opening 245 and a gate valve 244 configured to airtightly close the opening 245 are provided at a lower side wall of the lower vessel 211. By opening the gate valve 244, a loading/unloading port 245a is opened. In such a state, it is possible to transfer (load) the wafer 200 into the process chamber 201 or to transfer (unload) the wafer 200 from the process chamber 201 through the loading/unloading port 245a.

### <Susceptor>

A susceptor 217 is located at a bottom portion of the process chamber 201. The susceptor 217 serves as a substrate support (that is, a substrate mounting table) on which the wafer 200 is placed. For example, the susceptor 217 is made of a non-metallic material such as aluminum nitride (AlN), ceramic and quartz. The susceptor 217 is electrically insulated from the lower vessel 211.

A heater 217b serving as a heating structure is provided inside the susceptor 217. A heater power regulator (which is a heater power adjusting structure) 276 is connected to the heater 217b. The heater 217b is configured to heat the wafer 200 placed on the susceptor 217 to a predetermined temperature.

An impedance adjusting electrode 217c is provided inside the susceptor 217. The impedance adjusting electrode 217c is electrically grounded via a variable impedance regulator (which is an impedance adjusting structure) 275. The variable impedance regulator 275 includes components such as a coil and a variable capacitor. By adjusting at least one among an inductance and resistance of the coil and a capacitance of the variable capacitor, for example, it is possible to change (or vary) an impedance of the impedance adjusting electrode 217c within a range from substantially (or approximately) 0 Ω to a parasitic impedance value of the process chamber 201. With such a configuration, it is possible to uniformize a density of the plasma generated above the wafer 200, and it is also possible to control an electric potential (bias voltage) of the wafer 200 placed on the susceptor 217.

An elevator (which is an elevating structure) 268 configured to elevate and lower the susceptor 217 is provided at the bottom portion of the process chamber 201. A plurality of through-holes 217a are provided at the susceptor 217. A plurality of pins 266 are provided on a bottom surface of the lower vessel 211. For example, at least three of the through-holes 217a and at least three of the pins 266 are provided at positions facing one another. When the susceptor 217 is lowered by the elevator 268, upper ends of the pins 266 penetrate the through-holes 217a, respectively. Thereby, it is possible to hold (or support) the wafer 200 from thereunder by the pins 266.

### <Gas Supplier>

A gas supply head 236 through which a process gas is supplied into the process chamber 201 is provided above the upper vessel 210. The gas supply head 236 may include a lid 233 of a cap shape, a gas inlet port 234, a buffer chamber 237, an opening 238, a shield plate 240 and a gas outlet port 239. The buffer chamber 237 functions as a dispersion space in which the process gas to be introduced (supplied) into the process chamber 201 is dispersed.

A gas supply pipe 232a through which a first process gas is supplied, a gas supply pipe 232b through which a second process gas is supplied, and a gas supply pipe 232c through which an inert gas is supplied are connected to the gas inlet port 234 so as to be conjoined with one another. Gas supply sources (that is, a first process gas supply source 250a, a second process gas supply source 250b and an inert gas supply source 250c), mass flow controllers (MFCs) 252a, 252b and 252c serving as flow rate controllers and valves 253a, 253b and 253c serving as opening/closing valves are provided at the gas supply pipes 232a, 232b and 232c, respectively. A valve 243a is provided at a gas supply pipe 232 where the gas supply pipes 232a, 232b and 232c join.

A first process gas supplier (which is a first process gas supply structure or a first process gas supply system) is constituted mainly by the gas supply pipe 232a, the MFC 252a and the valve 253a. The first process gas supplier may further include the first process gas supply source 250a. A second process gas supplier (which is a second process gas supply structure or a second process gas supply system) is constituted mainly by the gas supply pipe 232b, the MFC 252b and the valve 253b. The second process gas supplier may further include the second process gas supply source 250b. An inert gas supplier (which is an inert gas supply structure or an inert gas supply system) is constituted mainly by the gas supply pipe 232c, the MFC 252c and the valve 253c. The inert gas supplier may further include the inert gas supply source 250c.

### Exhauster

An exhaust port 235 is provided on a side wall of the lower vessel 211. An exhaust pipe 231 is connected to the exhaust port 235. An APC (Automatic Pressure Controller) valve 242 serving as a pressure regulator (which is a pressure adjusting structure), a valve 243b serving as an opening/closing valve and a vacuum pump 246 serving as a vacuum exhaust apparatus are provided at the exhaust pipe 231. An exhauster (which is an exhaust structure or an exhaust system) is constituted mainly by the exhaust port 235, the exhaust pipe 231, the APC valve 242 and the valve 243b. The exhauster may further include the vacuum pump 246.

### <Plasma Generator>

The resonance coil 212 wound in a spiral shape to surround the process chamber 201 is provided on an outside of a side wall of the upper vessel 210. An RF (Radio Frequency) sensor 272, a high frequency power supply 273 and a matcher (which is a matching structure) 274 are connected to the resonance coil 212.

The high frequency power supply 273 is configured to supply a high frequency power to the resonance coil 212 via the RF sensor 272. The RF sensor 272 is configured to monitor information of a traveling wave or reflected wave of the high frequency power supplied from the high frequency power supply 273 to the resonance coil 212. The matcher 274 is configured to control the power (high frequency power) output from the high frequency power supply 273 to the resonance coil 212. For example, based on the information of the reflected wave monitored by the RF sensor 272, the matcher 274 is configured to control (or adjust) an impedance or an output frequency of the high frequency power from the high frequency power supply 273 so as to minimize an amplitude of the reflected wave.

The resonance coil 212 functions as a plasma generator (which is a plasma generating structure) configured to generate a standing wave when receiving the power from the high frequency power supply 273 and further configured to generate the plasma by creating a predetermined magnetic field in the plasma generation space. A winding diameter, a winding pitch and the number of winding turns of the resonance coil 212 are set such that the resonance coil 212 resonates when supplied with the power at a predetermined frequency. For example, the resonance coil 212 is configured to be capable of generating a magnetic field of about 0.01 Gauss to about 10 Gauss in the plasma generation space when the high frequency power whose frequency is within a range from 800 kHz to 50 MHz and whose power is within a range from 0.1 kW to 5 kW is applied. The resonance coil 212 is fixed to a base plate 248 using an insulator.

One end of the resonance coil 212 is electrically grounded via a movable tap 213, and the other end of the resonance coil 212 is electrically grounded via a fixed tap 214. A movable tap 215 is provided between both ends (which are electrically grounded) of the resonance coil 212. The movable tap 215 functions as a power feeder through which the high frequency power is supplied from the high frequency power supply 273. By adjusting connection positions of the movable taps 213 and 215 relative to the resonance coil 212, it is possible to set resonance characteristics of the resonance coil 212 to be suitable for output conditions of the high frequency power supply 273.

A shield plate 223 of a cylindrical shape is arranged around an outer periphery of the resonance coil 212. The shield plate 223 is configured to shield (or block) an electric field radiated outward from the resonance coil 212, and is further configured to form a capacitance component (C component) for constructing a resonance circuit between the shield plate 223 and the resonance coil 212. The C component serves as a part of components of the resonance circuit. For example, the shield plate 223 is made of a conductive material such as an aluminum alloy.

The plasma generator (plasma generating structure) is constituted mainly by the resonance coil 212. The plasma generator may further include the high frequency power supply 273, the RF sensor 272, the matcher 274, the movable taps 213 and 215 and the shield plate 223.

### Controller

A controller 221 serving as a control structure is configured to be capable of respectively controlling: the APC valve 242, the valve 243b and the vacuum pump 246 through a signal line “A”; the elevator 268 through a signal line “B”; the heater power regulator 276 and the variable impedance regulator 275 through a signal line “C”; the gate valve 244 through a signal line “D”; the RF sensor 272, the high frequency power supply 273 and the matcher 274 through a signal line “E”; and the MFCs 252a, 252b and 252c and the valves 253a, 253b, 253c and 243a through a signal line “F”.

As shown in FIG. 2, the controller 221 is constituted by a computer including a CPU (Central Processing Unit) 221a, a RAM (Random Access Memory) 221b, a memory 221c and an I/O port (input/output port) 221d. The RAM 221b, the memory 221c and the I/O port 221d are configured to be capable of exchanging data with the CPU 221a through an internal bus 221e. For example, an input/output device 222 (which is constituted by components such as a touch panel) is connected to the controller 221. In addition, the controller 221 is configured to be capable of being connected to an external memory 221t. For example, as the control structure, the processing apparatus 100 may include a single control structure, or may include a plurality of control structures. That is, a control operation of performing a process sequence described later may be performed using the single control structure, or may be performed using the plurality of control structures. In addition, the plurality of control structures may be configured as a control system in which they are connected to one another via a wired or wireless communication network, and an entirety of the control system may perform the control operation of performing the process sequence described later. Thus, in the present specification, the term “control structure” may refer to the single control structure, may refer to the plurality of control structures, or may refer to the control system configured by the plurality of control structures.

For example, the memory 221c is configured by a component such as a flash memory, a hard disk drive (HDD) and a solid state drive (SSD). For example, a control program configured to control an operation of the processing apparatus 100 and a process recipe containing information on procedures and conditions of a substrate processing described later may be readably stored in the memory 221c. The process recipe is obtained by combining steps (procedures) of the substrate processing described later such that the controller 221 can execute the steps by the processing apparatus 100 to acquire a predetermined result, and functions as a program. Hereinafter, the process recipe and the control program may be collectively or individually referred to as a “program”. In addition, the process recipe may also be simply referred to as a “recipe”. Thus, in the present specification, the term “program” may refer to the recipe alone, may refer to the control program alone or may refer to both of the recipe and the control program. The RAM 221b functions as a memory area (work area) where a program or data read by the CPU 221a is temporarily stored.

The I/O port 221d is electrically connected to the components described above such as the MFCs 252a, 252b and 252c, the valves 253a, 253b and 253c, 243a and 243b, the APC valve 242, the vacuum pump 246, the RF sensor 272, the high frequency power supply 273, the matcher 274, the variable impedance regulator 275, the heater power regulator 276, the gate valve 244 and the elevator 268.

The CPU 221a is configured to read and execute the control program stored in the memory 221c, and is further configured to read the recipe stored in the memory 221c in accordance with an instruction such as an operation command inputted via the input/output device 222. The CPU 221a is further configured to be capable of controlling various operations, in accordance with the recipe read from the memory 221c, such as flow rate adjusting operations for various gases by the MFCs 252a, 252b and 252c, opening and closing operations of the valves 253a, 253b, 253c, 243a and 243b, an operation of adjusting an opening degree of the APC valve 242, a start and stop of the vacuum pump 246, a power supply operation for the resonance coil 212 by the RF sensor 272, the high frequency power supply 273 and the matcher 274, an impedance value adjusting operation by the variable impedance regulator 275, a temperature adjusting operation for the heater 217b by the heater power regulator 276, an opening and closing operation of the gate valve 244, and an elevating and lowering operation for the susceptor 217 by the elevator 268.

The controller 221 may be configured by installing the above-mentioned program stored in the external memory 221t into the computer. For example, the external memory 221t may include a magnetic disk such as a hard disk drive (HDD), an optical disk such as a CD, a magneto-optical disk such as an MO and a semiconductor memory such as a USB memory and a solid state drive (SSD). The memory 221c or the external memory 221t may be embodied by a non-transitory computer readable recording medium. Hereafter, the memory 221c and the external memory 221t may be collectively or individually referred to as a “recording medium”. Thus, in the present specification, the term “recording medium” may refer to the memory 221c alone, may refer to the external memory 221t alone, or may refer to both of the memory 221c and the external memory 221t. The program may be provided to the computer without using the external memory 221t. For example, the program may be supplied to the computer using a communication interface such as the Internet and a dedicated line.

According to the present embodiments, the controller 221 further includes a calculator (which is a calculating structure) 221f. The calculator 221f is configured to be capable of exchanging data with components such as the CPU 221a, the RAM 221b, the memory 221c and the I/O port 221d through the internal bus 221e. The calculator 221f may be a function implemented by a specific hardware configuration, or may be a function implemented by a software configuration that the CPU 221a reads and executes the control program from the memory 221c. The calculator 221f may be configured as one of constituents of the controller 221 as shown in FIG. 2, or may be configured separately from the controller 221.

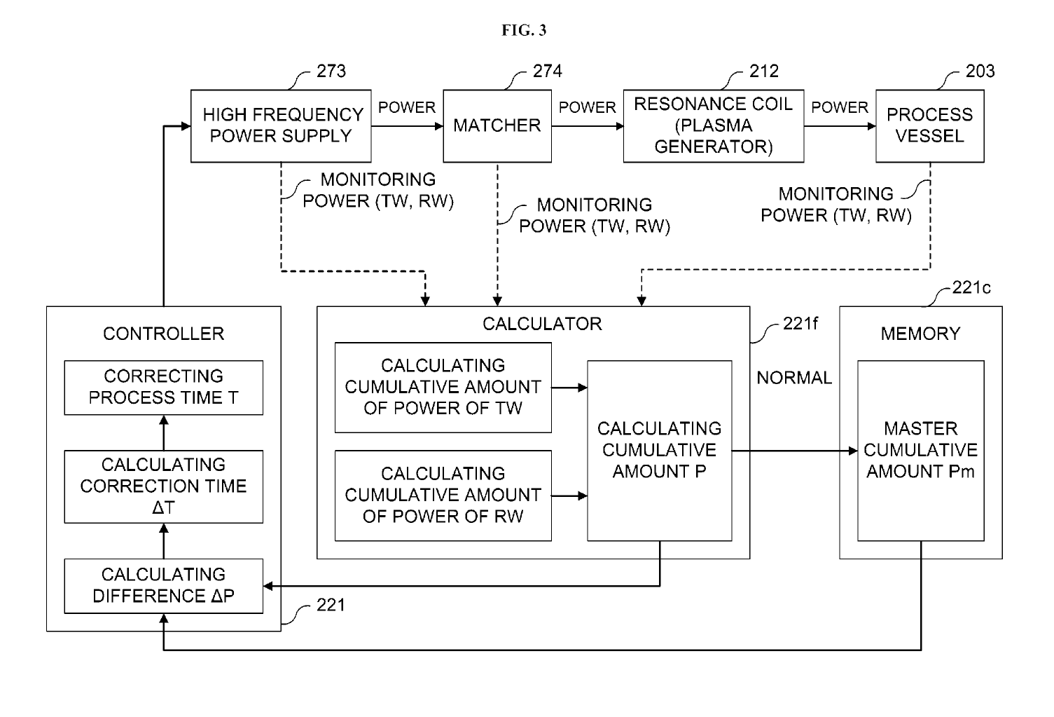

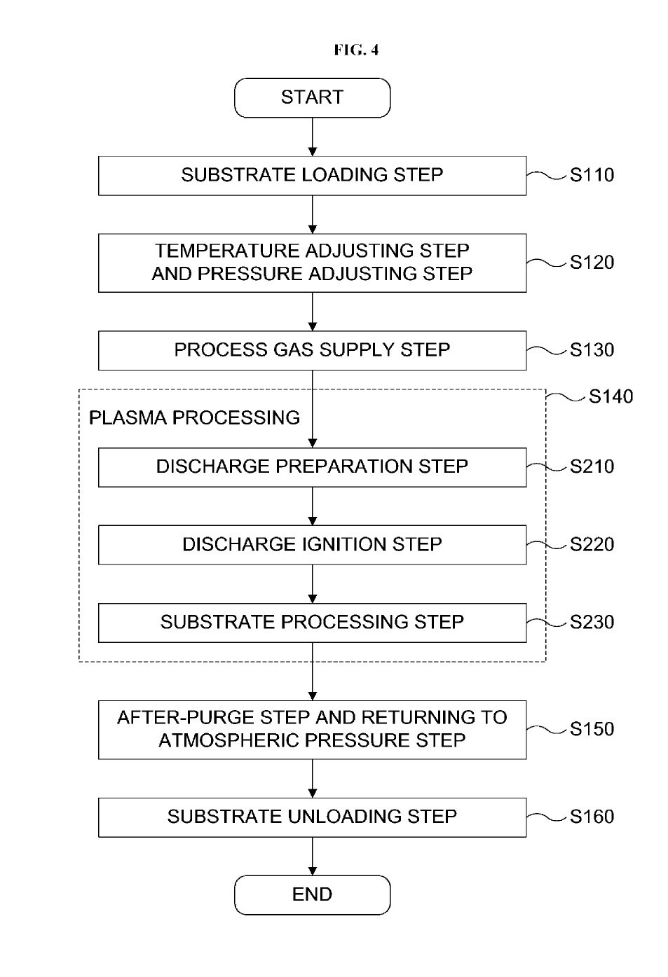

As shown in FIG. 3, the calculator 221f is configured to calculate a cumulative amount P of the power output by the plasma generator based on data such as information acquired by the controller 221 via the RF sensor 272 during a substrate processing step S230 described later. The cumulative amount P calculated by the calculator 221f may include a cumulative amount Pt of the power of the traveling wave (indicated by “TW” in FIG. 3) output by the plasma generator, and may include a cumulative amount Pr of the power of the reflected wave (indicated by “RW” in FIG. 3) output by the plasma generator. The calculator 221f is further configured to calculate the cumulative amount P in real time or repeatedly at a predetermined interval during the substrate processing step S230. The calculator 221f is configured to calculate the cumulative amount P during the substrate processing step S230 but refrain from calculating the cumulative amount P during a discharge preparation step S210 and a discharge ignition step S220 (which are described later).

In addition, as shown in FIG. 3, the memory 221c is configured to readably store, as a master cumulative amount Pm, the cumulative amount P calculated by the calculator 221f at an end of the substrate processing step S230 described later when a result of the substrate processing step S230 is normal.

In addition, as shown in FIG. 3, when controlling a progress of the substrate processing step S230 described later based on the recipe defining process conditions including a process time T, the controller 221 is configured to calculate a difference ΔP between the cumulative amount P calculated by the calculator 221f during the substrate processing step S230 and the master cumulative amount Pm stored in the memory 221c. In addition, the controller 221 is configured to calculate a correction time ΔT for the process time T based on the difference ΔP acquired as described above, and is further configured to adjust an end timing of the substrate processing step S230 based on the correction time ΔT. In the present specification, the term “process time” refers to a time duration of continuously performing a process related thereto. The same also applies to the following description.

Specifically, the controller 221 is configured to adjust the process time T in an increasing direction based on the correction time ΔT (that is, the process time T is adjusted to be increased based on the correction time ΔT) when the cumulative amount P after the process time T has elapsed is expected to be smaller than the master cumulative amount Pm. On the contrary, the controller 221 is configured to adjust the process time T in a decreasing direction based on the correction time ΔT (that is, the process time T is adjusted to be decreased based on the correction time ΔT) when the cumulative amount P after the process time T has elapsed is expected to be greater than the master cumulative amount Pm. In addition, the controller 221 is configured to refrain from adjusting the process time T based on the correction time ΔT when the cumulative amount P after the process time T has elapsed is expected to be equal to the master cumulative amount Pm (that is, there is no difference between the cumulative amount P after the process time T has elapsed and the master cumulative amount Pm). In addition, the controller 221 is configured to continue or stop the substrate processing step S230 in accordance with the adjusted process time T controller.

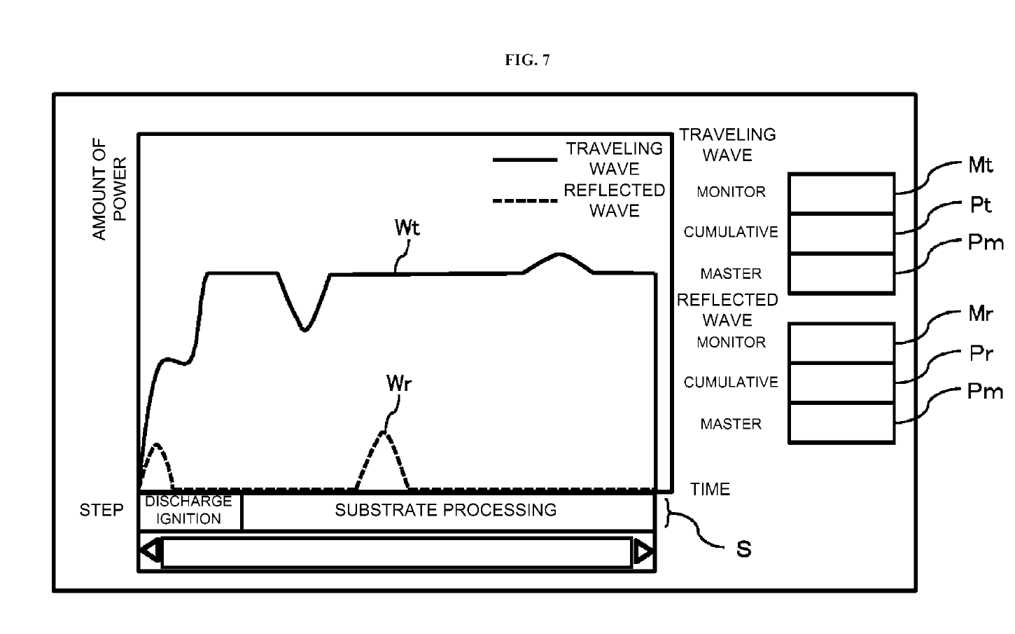

For example, as shown in FIG. 7, the input/output device 222 is configured to be capable of displaying a waveform Wt of the power of the traveling wave and a waveform Wr of the power of the reflected wave, which are output by the plasma generator based on data such as the information acquired by the controller 221 via the RF sensor 272. Specifically, the input/output device 222 is configured to display the waveform Wt of the power of the traveling wave (which is output by at least one among the resonance coil 212, the high frequency power supply 273 and the matcher 274) and the waveform Wr of the power of the reflected wave (which is output by at least one among the resonance coil 212, the high frequency power supply 273 and the matcher 274). The input/output device 222 is further configured to display a power value Mt of the traveling wave and a power value Mr of the reflected wave, which are monitored via the RF sensor 272.

The input/output device 222 is further configured to display the cumulative amount Pt of the power of the traveling wave and the cumulative amount Pr of the power of the reflected wave, which are calculated by the calculator 221f during the substrate processing step S230 described later. In addition, the input/output device 222 may be further configured to display the cumulative amount P to be acquired by adding the cumulative amount Pt of the power of the traveling wave and the cumulative amount Pr of the power of the reflected wave, instead of or in addition to the cumulative amount Pt and the cumulative amount Pr.

The input/output device 222 is further configured to display a progress status (step information S of the recipe) of the substrate processing step S230 described later, the cumulative amount P calculated by the calculator 221f during the substrate processing step S230 described later, and the master cumulative amount Pm read from the memory 221c. In addition, as described above, the cumulative amount P can be acquired by adding the cumulative amount Pt and the cumulative amount Pr. FIG. 7 is a diagram schematically illustrating an example in which the cumulative amount Pt and the cumulative amount Pr are displayed to effectively display the cumulative amount P.

Details of such configurations will be described in the substrate processing below.

### (2) Substrate Processing

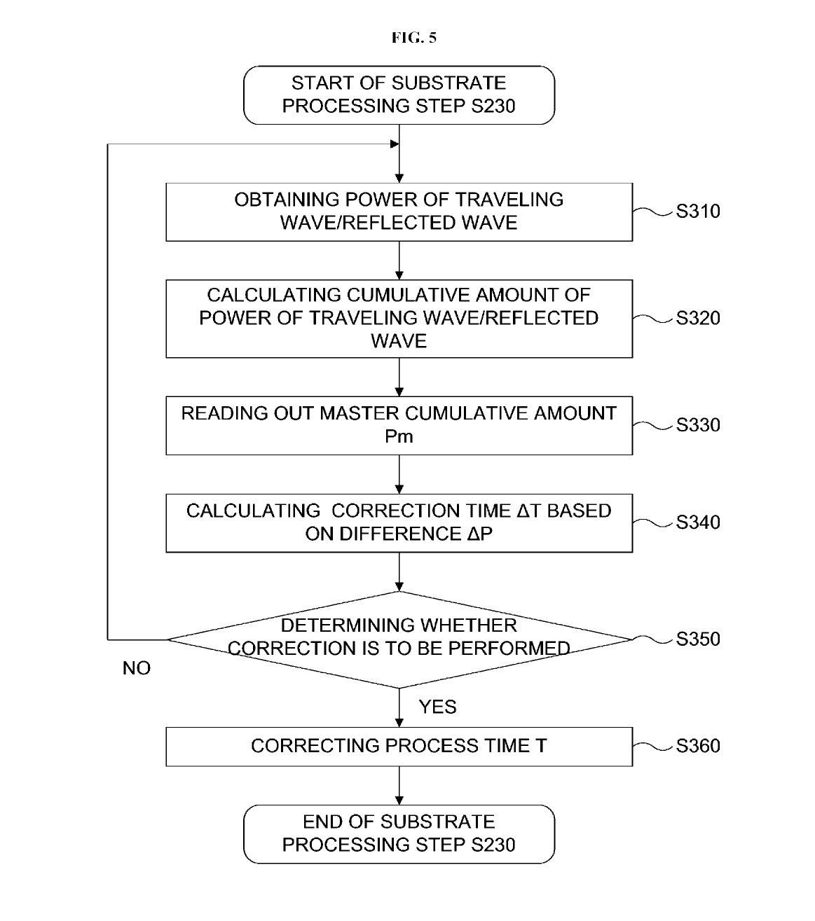

Hereinafter, a method of processing the substrate, which is a part of a process (method) of manufacturing a semiconductor device by using the processing apparatus 100 described above, that is, an example of the process sequence of processing the wafer 200 serving as the substrate with the plasma, will be described with reference to FIGS. 4, 5, 6A, 6B and 6C. In the following description, operations of components constituting the processing apparatus 100 are controlled by the controller 221.

### Substrate Loading Step: S110

First, the susceptor 217 is lowered by the elevator 268 such that the upper ends of the pins 266 protrude from an upper surface of the susceptor 217. Then, the gate valve 244 is opened, and the wafer 200 is loaded into the process chamber 201. After the wafer 200 is loaded, the gate valve 244 is closed to seal (or close) the process chamber 201. Then, the susceptor 217 is elevated by the elevator 268 such that the wafer 200 is transferred onto the susceptor 217.

### <Temperature Adjusting Step and Pressure Adjusting Step: S120>

The heater power regulator 276 adjusts a temperature of the heater 217b such that a temperature of the wafer 200 on the susceptor 217 can be set to a predetermined process temperature (temperature adjusting step). In addition, the vacuum pump 246 vacuum-exhausts an atmosphere (inner atmosphere) of the process chamber 201 while adjusting the opening degree of the APC valve 242 such that a pressure (inner pressure) of the process chamber 201 can be set to a predetermined process pressure (pressure adjusting step). Such a control is continuously performed at least until a plasma processing S140 described later is completed.

### Process Gas Supply Step: S130

The valves 253a and 253b are opened to supply the process gas (that is, the first process gas and the second process gas) into the gas supply pipes 232a and 232b. After flow rates of the first process gas and the second process gas are adjusted by the MFCs 252a and 252b, respectively, the first process gas and the second process gas whose flow rates are adjusted are supplied into the process chamber 201 through the gas supply pipe 232 and the gas supply head 236. In such an operation, the valve 253c may be opened to supply the inert gas into the process chamber 201 through the gas supply pipe 232 and the gas supply head 236. The process gas is continuously supplied into the process chamber 201 at least until the plasma processing S140 described below is completed.

### <Plasma Processing: S140>

Subsequently, the plasma processing S140 is performed. A progress of the plasma processing S140 is controlled based on the recipe that includes: a preparation recipe defining a preparatory processing including a plasma discharge and a plasma ignition; a main recipe defining a processing to be performed on the substrate (that is, the wafer 200); and a subsidiary recipe defining an additional processing to be performed on the substrate.

First, based on the preparation recipe, the plasma generator prepares for the plasma ignition (discharge preparation step S210). For example, the plasma processing S140 waits until the inner pressure of the process chamber 201 reaches a predetermined pressure and is stabilized. In addition, for example, the RF sensor 272, the high frequency power supply 273 and the matcher 274 prepare for the plasma ignition. In addition, for example, the variable impedance regulator 275 sets an initial value of the impedance.

Thereafter, based on the preparation recipe, the high frequency power is supplied from the high frequency power supply 273 to the resonance coil 212 such that the plasma generator starts generating the plasma (discharge ignition step S220). Thereby, the plasma (induced plasma) of the process gas is excited in the plasma generation space within the process chamber 201, and molecules of the process gas (which is excited into a plasma state) dissociates. As a result, various reactive species such as a radical and an ion are generated. It takes a certain amount of time for the plasma generated in the plasma generation space to stabilize. During such a time, for example, when the variable impedance regulator 275 adjusts the impedance, the power output by the plasma generator may become unstable.

When the generation of the plasma in the plasma generation space is stabilized, the processing on the wafer 200 is started based on the main recipe (substrate processing step S230). In such a processing, the reactive species contained in the plasma are uniformly and continuously supplied to a surface of the wafer 200. By reacting the reactive species with the surface of the wafer 200, it is possible to process the surface of the wafer 200. For example, by performing such a processing, it possible to form a film (which is obtained by modifying the surface of the wafer 200) on the surface of the wafer 200. For example, when the surface of the wafer 200 to be processed contains silicon (Si), a nitrogen-containing gas such as nitrogen (N₂) gas is used as the first process gas and a hydrogen-containing gas such as hydrogen (H₂) gas is used as the second process gas, it is possible to form a silicon nitride film (SiN film) of a predetermined thickness on the surface of the wafer 200.

For example, the process conditions for the substrate processing step S230 are as follows. Such information is defined in the main recipe described above.

The process temperature: from 150 °C to 750 °C;

The process pressure: from 1 Pa to 250 Pa, preferably from 1 Pa to 5 Pa;

The process time: from 1 second to 600 seconds, preferably from 120 seconds to 300 seconds;

A supply flow rate of the first process gas: from 0.02 slm to 5 slm, preferably from 0.1 slm to 1 slm;

A supply flow rate of the second process gas: from 0.02 slm to 5 slm, preferably from 0.1 slm to 1 slm;

A ratio of the supply flow rate of the first process gas to the supply flow rate of the second process gas: from 1:10 to 10:1;

A supply flow rate of the inert gas: from 0 slm to 10 slm;

An RF power: from 1 W to 5,000 W, preferably from 100 W to 3,500 W; and

An RF frequency: 13.5 MHz or 27 MHz.

Further, in the present specification, a notation of a numerical range such as “from 150 °C to 750 °C” means that a lower limit and an upper limit are included in the numerical range. Therefore, for example, a numerical range “from 150 °C to 750 °C” means a range equal to or higher than 150 °C and equal to or lower than 750 °C. The same also applies to other numerical ranges described in the present specification. Further, in the present specification, the process temperature may refer to the temperature of the wafer 200 or the inner temperature of the process chamber 201, and the process pressure may refer to the inner pressure of the process chamber 201. In addition, when a supply flow rate of a gas is zero (0) slm, it refers to a case where the gas is not supplied. In addition, the RF power may refer to the high frequency power output by the plasma generator, and the RF frequency may refer to the frequency of the high frequency power output by the plasma generator.

As the first process gas, for example, the nitrogen-containing gas such as nitrogen (N₂) gas, ammonia (NH₃) and hydrazine (H₂N₄) may be used. As the first process gas, for example, one or more of the gases exemplified above may be used.

As the second process gas, for example, a hydrogen-containing gas such as hydrogen (H₂) gas and deuterium (D₂) gas may be used. As the second process gas, for example, one or more of the gases exemplified above may be used.

In addition, at least one gas among the first process gas and the second process gas, for example, an oxygen-containing gas such as oxygen (O₂) gas, ozone (O₃) gas, nitrous oxide (N₂O) gas, nitric oxide (NO) gas, nitrogen dioxide (NO₂) gas, carbon dioxide (CO₂) gas and carbon monoxide (CO) gas may be used. As the process gas, for example, one or more of the gases exemplified above may be used.

As the inert gas, for example, nitrogen (N₂) gas or a rare gas such as argon (Ar) gas, helium (He) gas, neon (Ne) gas and xenon (Xe) gas may be used. As the inert gas, for example, one or more of the gases exemplified above may be used.

The substrate processing step S230 is performed in a manner described above. However, regarding a stability of the substrate processing step S230, the following issues exist.

As described above, the substrate processing step S230 is started after the generation of the plasma in the plasma generation space is stabilized. However, even after the substrate processing step S230 is started, the power output by the plasma generator may temporarily fluctuate due to various factors. FIG. 7 is a diagram schematically illustrating examples of the waveform Wt of the power of the traveling wave and the waveform Wr of the power of the reflected wave, which are output by the plasma generator. In FIG. 7, a solid line indicates the waveform Wt of the power of the traveling wave, and a dashed line indicates the waveform Wr of the power of the reflected wave.

As shown in the waveforms shown in FIG. 7, the power of the traveling wave output by the plasma generator may temporarily decrease or increase. In addition, although the power of the reflected wave output by the plasma generator is controlled by the matcher 274 so as to minimize the amplitude of the reflected wave, the power of the reflected wave may temporarily increase. Such temporary fluctuations in the power output by the plasma generator may increase or decrease the cumulative amount of the power output by the plasma generator in a single execution (single run) of the substrate processing step S230, that is, may result in an excess or deficiency in a total amount of the reactive species supplied to the wafer 200 in the single execution of the substrate processing step S230 (an excess or deficiency in the plasma processing). In such a case, the degree of the plasma processing on the wafer 200 may deviate from a target degree. As a result, a thickness or a quality of the film formed on the surface of the wafer 200 may deviate from a target value related thereto.

However, when the cumulative amount of the power output by the plasma generator is expected to decrease (that is, when a supply amount of the power for the processing is expected to be insufficient), by adjusting the process time T to be increased in the substrate processing step S230, it is possible to compensate for the deficiency in the plasma processing. In addition, when the cumulative amount of the power output by the plasma generator is expected to increase (that is, when the supply amount of the power for the processing is expected to be excessive), by adjusting the process time T to be decreased in the substrate processing step S230, it is possible to eliminate the excess in the plasma processing. Therefore, according to the present embodiments, the cumulative amount P of the power output by the plasma generator is calculated during the substrate processing step S230, and the process time T for the substrate processing step S230 is corrected (or adjusted) based on a result of such calculation. Thereby, it is possible to adjust the end timing of the substrate processing step S230.

### Correction Process of Process time T

Hereinafter, a correction process of the process time T (that is, a process of correcting the process time T) for the substrate processing step S230 will be described in detail with reference to FIG. 5.

After the generation of the plasma in the plasma generation space is stabilized and the substrate processing step S230 is started, the calculator 221f acquires information on the power of the traveling wave and information on the power of the reflected wave, which are output by the plasma generator via the RF sensor 272 (S310). Such information on the power is acquired via the RF sensor 272 or the like from at least one among the high frequency power supply 273, the matcher 274 and the resonance coil 212.

Based on the information on the power acquired as described above, the calculator 221f calculates the cumulative amount Pt of the power of the traveling wave output by the plasma generator, and also calculates the cumulative amount Pr of the power of the reflected wave output by the plasma generator (S320). An acquisition of the information on the power (that is, the step S310) and a calculation of the cumulative amount (that is, the step S320) by the calculator 221f may be performed in real time after the substrate processing step S230 is started, or may be repeatedly performed at a predetermined interval (for example, every 50 msec to every 200 msec).

The calculator 221f then adds the cumulative amounts Pt and Pr acquired as described above, and sets the sum as the cumulative amount P of the power output by the plasma generator. The calculator 221f passes the cumulative amount P calculated as described above to the controller 221. When an effect of the fluctuation in the power of the reflected wave on the substrate processing step S230 is negligibly small, the cumulative amount Pr of the power of the reflected wave may not be included in the sum, the cumulative amount Pt of the power of the traveling wave alone may be used as the cumulative amount P, and the cumulative amount Pt used as the cumulative amount P may be passed to the controller 221. On the contrary, when an effect of the fluctuation in the power of the traveling wave on the substrate processing step S230 is negligibly small, the cumulative amount Pt of the power of the traveling wave may not be included in the sum, the cumulative amount Pr of the power of the reflected wave alone may be used as the cumulative amount P, and the cumulative amount Pr used as the cumulative amount P may be passed to the controller 221.

When receiving the cumulative amount P from the calculator 221f, the controller 221 reads the master cumulative amount Pm from the memory 221c (S330). As described above, the master cumulative amount Pm refers to the cumulative amount P calculated by the calculator 221f at the end of the substrate processing step S230 when the result of the substrate processing step S230 is normal. In other words, the master cumulative amount Pm refers to the cumulative amount of the power to be output by the plasma generator when the substrate processing step S230 is performed normally without the excess or deficiency. The master cumulative amount Pm is stored in the memory 221c in advance before the substrate processing step S230 is started. In a case where the substrate processing step S230 is repeatedly performed, when a result of a previous execution (run) of the substrate processing step S230 is normal, the cumulative amount P calculated by the calculator 221f at an end of the previous execution of the substrate processing step S230 may be used as the master cumulative amount Pm.

Subsequently, the controller 221 compares the cumulative amount P calculated by the calculator 221f during the substrate processing step S230 with the master cumulative amount Pm read from the memory 221c, and then calculates the difference ΔP therebetween. Then, based on the difference ΔP, the controller 221 calculates the correction time ΔT to correct the process time T for the substrate processing step S230 (S340). The controller 221 is configured to adjust the process time T such that the process time T is adjusted to be increased based on the correction time ΔT (that is, the correction time ΔT is set to increase the process time T) when the cumulative amount P after the process time T has elapsed is expected to be smaller than the master cumulative amount Pm. On the contrary, the controller 221 is configured to, when the cumulative amount P after the process time T has elapsed is expected to be greater than the master cumulative amount Pm, adjust the process time T such that the process time T is adjusted to be decreased based on the correction time ΔT (that is, the correction time ΔT is set to decrease the process time T). In addition, the correction time ΔT is set such that the process time T remains unchanged when the cumulative amount P after the process time T has elapsed is expected to be equal to the master cumulative amount Pm (that is, there is no difference between the cumulative amount P after the process time T has elapsed and the master cumulative amount Pm).

The controller 221 then determines whether or not to correct the process time T based on the correction time ΔT acquired as described above (S350).

When it is determined, in the step S350 of determining whether or not to correct the process time T, that the process time T is to be corrected (“YES” in FIG. 5), the controller 221 corrects the process time T as follows (S360).

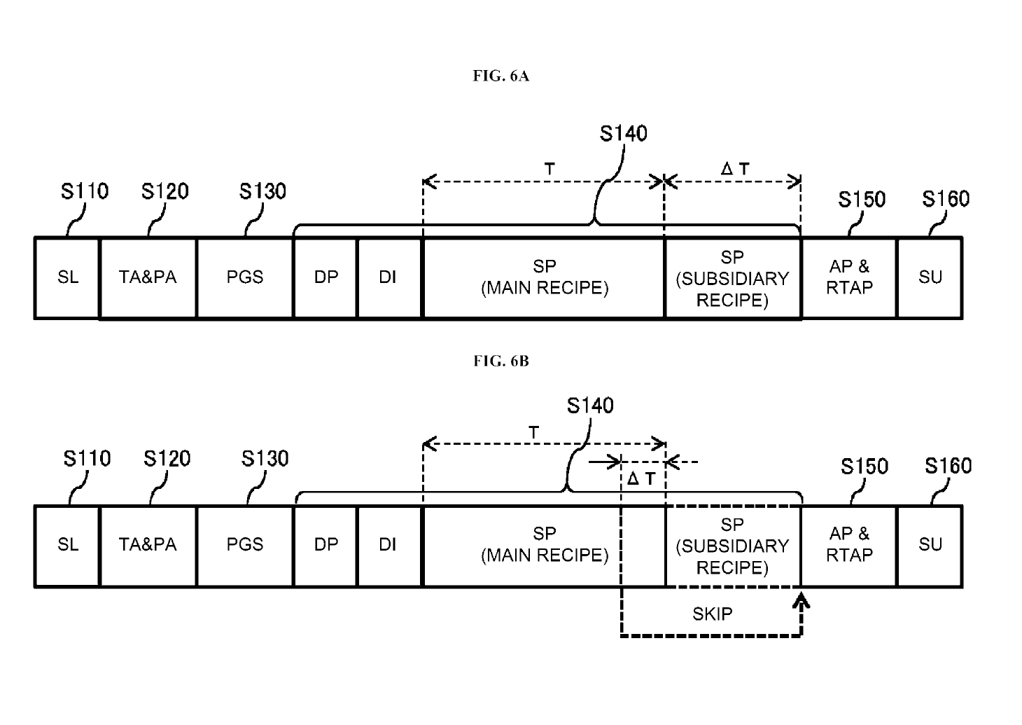

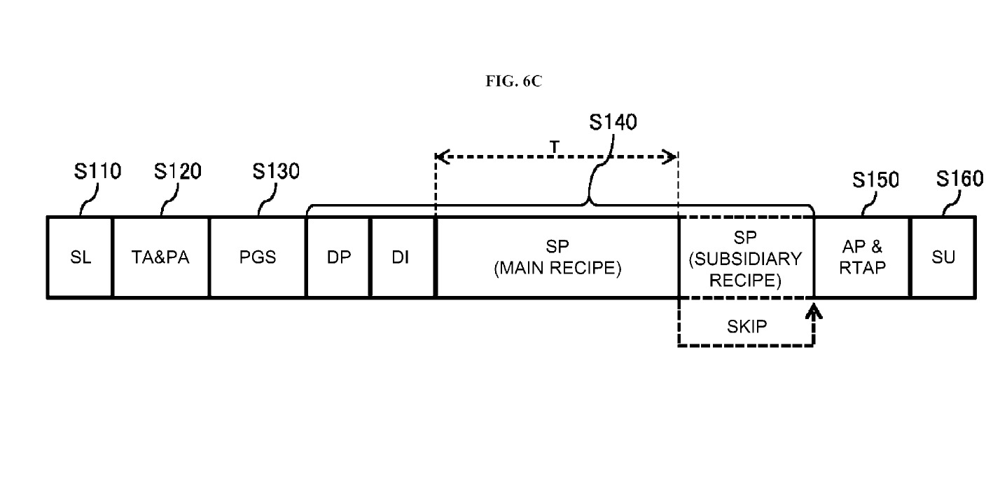

For example, when the cumulative amount P after the process time T has elapsed is expected to be smaller than the master cumulative amount Pm, the controller 221 adjusts the process time T such that the process time T is adjusted to be increased based on the correction time ΔT. In such a case, various control methods are conceivable. However, according to the present embodiments, as shown in FIG. 6A, an execution of the main recipe is completed as defined (that is, with the process time T unchanged), and then the subsidiary recipe whose process conditions other than the process time are defined the same as the process conditions defined in the main recipe is performed for a period of time equivalent to the correction time ΔT. As a result, the process time T is effectively increased (that is, “corrected process time T” = “process time T defined in the recipe” + “correction time ΔT”). In FIGS. 6A to 6C, “SL” represents the substrate loading step S110, “TA & PA” represents the temperature adjusting step and the pressure adjusting step (that is, the step S120), “PGS” represents the process gas supply step S130, “DP” represents the discharge preparation step S210, “DI” represents the discharge ignition step S220, “SP” represents the substrate processing step S230, “AP & RTAP” represents an after-purge step and a returning to the atmospheric pressure step (that is, a step S150), and “SU” represents a substrate unloading step S160.

On the contrary, for example, when the cumulative amount P after the process time T has elapsed is expected to be greater than the master cumulative amount Pm, the controller 221 adjusts the process time T such that the process time T is adjusted to be decreased based on the correction time ΔT. Even in such a case, various control methods are conceivable. However, according to the present embodiments, as shown in FIG. 6B, the execution of the main recipe is terminated early (that is, aborted) at a timing when a remaining process time of the main recipe becomes equal to the correction time ΔT, and the subsidiary recipe is not performed thereafter. As a result, the process time T is effectively decreased (that is, “corrected process time T” = “process time T defined in the recipe” - “correction time ΔT”). In the present specification, when “the subsidiary recipe is not performed”, it may include a case where the subsidiary recipe is nominally performed by setting the process time of the subsidiary recipe to zero, that is, a case where the subsidiary recipe is effectively skipped.

When it is determined, in the step S350 of determining whether or not to correct the process time T, that the process time T is not to be corrected (“NO” in FIG. 5), that is, when the cumulative amount P after the process time T has elapsed is expected to be equal to the master cumulative amount Pm, the controller 221 does not adjust the process time T based on the correction time ΔT. Even in such a case, various control methods are conceivable. However, according to the present embodiments, as shown in FIG. 6C, the execution of the main recipe is completed as defined (that is, with the process time T unchanged), and then the subsidiary recipe, and the subsidiary recipe is not performed thereafter. As a result, the process time T remains unchanged (that is, “corrected process time T” = “process time T defined in the recipe”).

For example, when it is determined, in the step S350 of determining whether or not to correct the process time T, that the process time T is not to be corrected (“NO” in FIG. 5), the process time T remains unchanged, and the correction process (that is, the steps S310 to S350) mentioned above is then performed again.

By performing the correction process mentioned above, the controller 221 is configured to be capable of appropriately adjusting the end timing of the substrate processing step S230 while appropriately performing (or continuing) or stopping the substrate processing step S230 in accordance with the process time T adjusted by controller. In addition, when stopping the substrate processing step S230, a supply of the high frequency power from the high frequency power supply 273 to the resonance coil 212 is stopped, and the generation of the plasma in the plasma generation space is also stopped. In addition, the valves 253a and 253b are closed to stop a supply of the process gas into the process chamber 201.

It is preferable to perform the correction process mentioned above a predetermined number of times (one or more times, preferably a plurality of times) during the substrate processing step S230. The correction process may be repeatedly performed at a regular interval during the substrate processing step S230, or may be performed a plurality of times at a short interval only shortly before the end of the substrate processing step S230.

In addition, as described above, it is preferable that the calculator 221f does not calculate the cumulative amount P during the discharge preparation step S210 and the discharge ignition step S220, but calculates the cumulative amount P during the substrate processing step S230. In other words, it is preferable that the calculator 221f does not calculate the cumulative amount P during an execution of the preparation recipe, but calculates the cumulative amount P during the execution of the main recipe. During the discharge ignition step S220, the power output by the plasma generator may become unstable. Therefore, by excluding the discharge preparation step S210 and the discharge ignition step S220 from a target period for calculating the cumulative amount P, it is possible to more accurately correct the process time T.

### After-purge Step and Returning to Atmospheric Pressure Step: S150

After the substrate processing step S230 is completed, as shown in FIG. 4, the plasma processing S140 is considered to be completed, and the valve 253c is opened to supply the inert gas into the process chamber 201 through the gas supply pipe 232 and the gas supply head 236. Thereby, the inner atmosphere of the process chamber 201 is purged with the inert gas. As a result, it is possible to remove a substance (such as the gas remaining in the process chamber 201 and reaction by-products remaining in the process chamber 201) from the process chamber 201 (after-purge step). Thereafter, the inner atmosphere of the process chamber 201 is replaced with the inert gas, and the inner pressure of the process chamber 201 is returned to the normal pressure (atmospheric pressure) (returning to atmospheric pressure step).

### Substrate Unloading Step: S160

The susceptor 217 is lowered by the elevator 268 until the upper ends of the pins 266 protrude from the upper surface of the susceptor 217 such that the wafer 200 is transferred onto the pins 266. Then, the gate valve 244 is opened, and the wafer 200 is transferred (unloaded) from the process chamber 201. Thereby, the substrate processing according to the present embodiments is completed.

### (3) Effects according to Present Embodiments

According to the present embodiments, it is possible to obtain one or more of the following effects.

(a) During the substrate processing step S230, the difference ΔP between the cumulative amount P calculated by the calculator 221f and the master cumulative amount Pm read from the memory 221c is calculated, the correction time ΔT for the process time T is calculated based on the difference ΔP, and the end timing of the substrate processing step S230 is adjusted based on the correction time ΔT. Thereby, even when the cumulative amount of the power output by the plasma generator in the single execution of the substrate processing step S230 is increased or decreased, it is possible to match the quality of the substrate processing using the plasma (that is, a processing amount) to a target degree (that is, a target processing amount). As a result, it is possible to stabilize a quality of the plasma processing, and it is also possible to improve the yield.

(b) The cumulative amount P includes the cumulative amount Pt of the power of the traveling wave and the cumulative amount Pr of the power of the reflected wave (which are output by the plasma generator). Thereby, it is possible to accurately perform the control mentioned above. In addition, it is possible to stabilize the quality of the plasma processing, and it is also possible to improve the yield.

(c) The calculator 221f calculates the cumulative amount P in real time or repeatedly calculates the cumulative amount P at a predetermined interval (for example, every 50 msec to every 200 msec) during the substrate processing step S230. Thereby, it is possible to accurately perform the control mentioned above. In addition, it is possible to stabilize the quality of the plasma processing, and it is also possible to improve the yield.

(d) When the cumulative amount P after the process time T has elapsed is expected to be smaller than the master cumulative amount Pm, the process time T is adjusted to be increased based on the correction time ΔT. Thereby, it is possible to accurately perform the control mentioned above. For example, as in the present embodiments, in a case where the cumulative amount P when the main recipe is performed as defined is expected to be smaller than the master cumulative amount Pm, the execution of the main recipe is completed as defined, and then the subsidiary recipe is performed. As a result, the process time T is effectively increased. Thereby, it is possible to accurately perform the control mentioned above.

(e) When the cumulative amount P after the process time T has elapsed is expected to be greater than the master cumulative amount Pm, the process time T is adjusted to be decreased based on the correction time ΔT. Thereby, it is possible to accurately perform the control mentioned above. For example, as in the present embodiments, in a case where the cumulative amount P when the main recipe is performed as defined is expected to be greater than the master cumulative amount Pm, the execution of the main recipe is terminated at the timing when the remaining process time of the main recipe becomes equal to the correction time ΔT, and the subsidiary recipe is not performed thereafter. As a result, the process time T is effectively decreased. Thereby, it is possible to accurately perform the control mentioned above.

(f) When the cumulative amount P after the process time T has elapsed is expected to be equal to the master cumulative amount Pm (that is, there is no difference between the cumulative amount P after the process time T has elapsed and the master cumulative amount Pm), the process time T is not adjusted based on the correction time ΔT. Thereby, it is possible to accurately perform the control mentioned above. For example, as in the present embodiments, in a case where the cumulative amount P when the main recipe is performed as defined is expected to be equal to the master cumulative amount Pm, the execution of the main recipe is completed as defined, and then the subsidiary recipe is not performed thereafter. As a result, the process time T remains unchanged. Thereby, it is possible to accurately perform the control mentioned above.

(g) By performing (or continuing) or stopping the substrate processing step S230 in accordance with the process time T adjusted by the controller in such a manner, it is possible to accurately perform the control mentioned above. In addition, it is possible to stabilize the quality of the plasma processing, and it is also possible to improve the yield.

(h) The input/output device 222 displays the waveform Wt of the power of the traveling wave output by the plasma generator and the waveform Wr of the power of the reflected wave output by the plasma generator. Thereby, an operator (operating personnel) can easily check (or confirm) that the progress of the substrate processing step S230 is being performed normally. That is, since the input/output device 222 displays the waveform Wt of the power of the traveling wave output by at least one among the resonance coil 212, the high frequency power supply 273 and the matcher 274 and the waveform Wr of the power of the reflected wave output by at least one among the resonance coil 212, the high frequency power supply 273 and the matcher 274, the operator can easily confirm the normal progress of the substrate processing step S230.

(i) The input/output device 222 displays the cumulative amount Pt of the power of the traveling wave output by the plasma generator and the cumulative amount Pr of the power of the reflected wave output by the plasma generator. Thereby, the operator can easily check that the progress of the substrate processing step S230 is being performed normally.

(j) The input/output device 222 displays the progress status (that is, step information S of the recipe) of the substrate processing step S230, the cumulative amount P calculated during the substrate processing step S230 and the master cumulative amount Pm read from the memory 221c. Thereby, the operator can easily check that the progress of the substrate processing step S230 is being performed normally.

(k) The cumulative amount P is not calculated during the execution of the preparation recipe, but calculated during the execution of the main recipe. Thereby, it is possible to accurately correct the process time T. As a result, it is possible to stabilize the quality of the plasma processing, and it is also possible to improve the yield.

### Other Embodiments of Present disclosure

While the technique of the present disclosure is described in detail by way of the embodiments mentioned above, the technique of the present disclosure is not limited thereto. The technique of the present disclosure may be modified in various ways without departing from the scope thereof. Hereinafter, other embodiments of the present disclosure will be described. Unless otherwise specified, process procedures and the process conditions for each step in the other embodiments of the present disclosure described below may be substantially the same as the process procedures and the process conditions for each step in the process sequence described above.

For example, the embodiments mentioned above are described by way of an example in which, as an example of the substrate processing step S230, the nitrogen-containing gas or the hydrogen-containing gas is used as the process gas to form the SiN film on the substrate whose surface contains silicon (Si). However, the technique of the present disclosure is not limited thereto. For example, the technique of the present disclosure may be preferably applied when a gas such as the oxygen-containing gas, a carbon-containing gas, a silicon-containing gas and a metal-element-containing gas is used as the process gas to form a film other than the SiN film on the substrate. Even in such a case, it is possible to obtain substantially the same effects as in the embodiments mentioned above.

For example, the embodiments mentioned above are described by way of an example in which the film is formed by modifying the surface of the substrate using the plasma in the substrate processing step S230. However, the technique of the present disclosure is not limited thereto. For example, the film may be deposited on the surface of the substrate using the plasma in the substrate processing step S230. In addition, for example, the surface of the substrate may be etched using the plasma in the substrate processing step S230. Even in such cases, it is possible to obtain substantially the same effects as in the embodiments mentioned above.

It is preferable that the recipe used to perform each process is prepared individually in accordance with contents of each process. For example, it is preferable that a plurality of recipes are stored in the memory 221c in advance via an electric communication line or the external memory 221t. Then, when starting each process, the CPU 221a preferably selects the appropriate recipe among the recipes stored in the memory 221c in accordance with the contents of each process. With such a configuration, various films of different types, different composition ratios, different qualities and different thicknesses can be formed with a high reproducibility using a single processing apparatus. In addition, since a burden on the operator can be reduced, each process can be started quickly while avoiding a misoperation of the processing apparatus 100.

In addition, the recipe described above is not limited to creating a new recipe. For example, the recipe may be prepared by changing an existing recipe installed in the processing apparatus 100 in advance. When changing the existing recipe to the new recipe, the new recipe may be installed in the processing apparatus 100 via the electric communication line or the recording medium in which the new recipe is stored. For example, the existing recipe already installed in the processing apparatus 100 may be directly changed to the new recipe by operating the input/output device 222 of the processing apparatus 100.

For example, the embodiments mentioned above are described by way of an example in which a single wafer type processing apparatus capable of processing one or several substrates at once is used. However, the technique of the present disclosure is not limited thereto. For example, the technique of the present disclosure may be preferably applied when a batch type processing apparatus capable of simultaneously processing a plurality of substrates is used. For example, the embodiments mentioned above are described by way of an example in which a processing apparatus including a cold wall type process furnace is used. However, the technique of the present disclosure is not limited thereto. For example, the technique of the present disclosure may be preferably applied when a processing apparatus including a hot wall type process furnace is used.

Process procedures and process conditions of each process using the processing apparatuses exemplified above may be substantially the same as those of the embodiments or the modified examples mentioned above. Even in such a case, it is possible to obtain substantially the same effects as in the embodiments or the modified examples mentioned above.

In addition, the embodiments and the modified examples mentioned above may be appropriately combined. The process procedures and the process conditions of each combination thereof may be substantially the same as those of the embodiments or the modified examples mentioned above.

According to some embodiments of the present disclosure, it is possible to stabilize the quality of the plasma processing performed on the substrate.

What is claimed is:

1. A substrate processing apparatus comprising:
a process vessel in which a substrate is accommodated and processed;
a plasma generator configured to generate a plasma in the process vessel;
a calculator configured to calculate a cumulative amount of an electric power output by the plasma generator during a processing of the substrate;
a memory configured to store, as a master cumulative amount, the cumulative amount at an end of the processing of the substrate when a result of the processing of the substrate is normal; and
a controller configured to be capable of controlling a progress of the processing of the substrate based on a recipe defining process conditions containing a process time for the substrate, and capable of calculating a correction time for the process time from a difference between the cumulative amount calculated by the calculator and the master cumulative amount.

2. The substrate processing apparatus of claim 1, wherein the controller is further configured to be capable of adjusting an end timing of the processing of the substrate based on the correction time.

3. The substrate processing apparatus of claim 1, wherein the cumulative amount comprises a cumulative amount of an electric power of a traveling wave output by the plasma generator.

4. The substrate processing apparatus of claim 1, wherein the cumulative amount comprises a cumulative amount of an electric power of a reflected wave output by the plasma generator.

5. The substrate processing apparatus of claim 1, wherein the calculator is further configured to calculate the cumulative amount in real time or repeatedly calculate the cumulative amount at a predetermined interval during the processing of the substrate.

6. The substrate processing apparatus of claim 1, wherein the controller is further configured to adjust the process time to be increased based on the correction time when the cumulative amount after the process time has elapsed is expected to be smaller than the master cumulative amount.

7. The substrate processing apparatus of claim 1, wherein the controller is further configured to adjust the process time to be decreased based on the correction time when the cumulative amount after the process time has elapsed is expected to be greater than the master cumulative amount.

8. The substrate processing apparatus of claim 1, wherein the controller is further configured such that the process time is not adjusted based on the correction time when the cumulative amount after the process time has elapsed is expected to be equal to the master cumulative amount.

9. The substrate processing apparatus of claim 6, wherein the controller is further configured to continue or stop the processing of the substrate in accordance with the process time adjusted by the controller.

10. The substrate processing apparatus of claim 7, wherein the controller is further configured to continue or stop the processing of the substrate in accordance with the process time adjusted by the controller.

11. The substrate processing apparatus of claim 1, further comprising
an input/output device configured to display a waveform of an electric power of a travelling wave output by the plasma generator and a waveform of an electric power of a reflected wave output by the plasma generator.

12. The substrate processing apparatus of claim 11, wherein the input/output device is further configured to display a progress status of the processing of the substrate, the cumulative amount calculated during the processing of the substrate and the master cumulative amount.

13. The substrate processing apparatus of claim 1, wherein the recipe comprises:
a preparation recipe defining a preparatory processing containing a plasma discharge and a plasma ignition;
a main recipe defining a processing to be performed on the substrate; and
a subsidiary recipe defining an additional processing to be performed on the substrate.

14. The substrate processing apparatus of claim 13, wherein the calculator is further configured to calculate the cumulative amount during an execution of the main recipe and configured not to calculate the cumulative amount during an execution of the preparation recipe.

15. The substrate processing apparatus of claim 13, wherein the controller is further configured to, in a case where the cumulative amount when the main recipe is performed as defined is expected to be smaller than the master cumulative amount, complete an execution of the main recipe as defined and then continue an execution of the subsidiary recipe.

16. The substrate processing apparatus of claim 13, wherein the controller is further configured to, in a case where the cumulative amount when the main recipe is performed as defined is expected to be greater than the master cumulative amount, terminate an execution of the main recipe at a timing where a remaining process time of the main recipe is equal to the correction time and then refrain from performing the subsidiary recipe.

17. The substrate processing apparatus of claim 13, wherein the controller is further configured to, in a case where the cumulative amount when the main recipe is performed as defined is expected to be equal to the master cumulative amount, complete an execution of the main recipe as defined and then refrain from performing the subsidiary recipe.

18. A substrate processing method comprising:
(a) generating a plasma in a space in which a substrate is accommodated;
(b) processing the substrate based on a recipe defining process conditions containing a process time for the substrate;
(c) calculating a cumulative amount of an electric power used to generate the plasma during a processing of the substrate;
(d) storing, as a master cumulative amount, the cumulative amount at an end of the processing of the substrate when a result of the processing of the substrate is normal; and
(e) calculating a correction time for the process time from a difference between the cumulative amount calculated during the processing of the substrate and the master cumulative amount.

19. A method of manufacturing a semiconductor device, comprising
the method of claim 18.

20. A non-transitory computer-readable recording medium storing a program that causes a substrate processing apparatus, by a computer, to perform:
(a) generating a plasma in a space in which a substrate is accommodated;
(b) processing the substrate based on a recipe defining process conditions containing a process time for the substrate;
(c) calculating a cumulative amount of an electric power used to generate the plasma during a processing of the substrate;
(d) storing, as a master cumulative amount, the cumulative amount at an end of the processing of the substrate when a result of the processing of the substrate is normal; and
(e) calculating a correction time for the process time from a difference between the cumulative amount calculated during the processing of the substrate and the master cumulative amount.
